(19) United States
(12) Patent Application Publication
(10) Pub. No.: US 2020/0028040 A1
(43) Pub. Date: Jan. 23, 2020

(54) LIGHT-EMITTING DEVICE AND METHOD OF PRODUCING THE SAME

(71) Applicant: Dexerials Corporation, Shinagawa-ku Tokyo (JP)

(72) Inventors: Shuji OHASHI, Oyama-shi, Tochigi (JP); Takehiro YAMASUGE, Utsunomiya-shi, Tochigi (JP); Moriaki ABE, Utsunomiya-shi, Tochigi (JP); Kazuhiro YAGIHASHI, Miyagi-gun, Miyagi (JP); Tsuneo KUSUNOKI, Sagamihara-shi, Kanagawa (JP)

(73) Assignee: Dexerials Corporation, Shinagawa-ku Tokyo (JP)

(21) Appl. No.: 16/338,058

(22) PCT Filed: Aug. 25, 2017
(86) PCT No.: PCT/JP2017/030534

§ 371 Date: Mar. 29, 2019

(30) Foreign Application Priority Data
Sep. 30, 2016 (JP) 2016-194456

(51) Int. Cl. H01L 33/56; H01L 33/60; H01L 33/50

(52) U.S. Cl. CPC H01L 33/56; H01L 33/60; H01L 33/502; H01L 2933/0041; H01L 2933/0058; H01L 2933/005; H01L 33/507

(57) ABSTRACT

A light-emitting device includes a light-emitting element; one or more silver-based members having silver on their surfaces; and a resin layer including a first resin layer covering at least one of the silver-based members, and a second resin layer placed directly on the first resin layer. The light-emitting element is covered with the first resin layer or both the first resin layer and the second resin layer, at least one of the first resin layer and the second resin layer contains an inorganic adsorbent which chemically adsorbs a sulfide, the second resin layer contains a sulfide-based phosphor, and a ratio of a thickness of the first resin layer with respect to a total thickness of the first resin layer and the second resin layers is 50% or more.

### CROSS-REFERENCE TO RELATED APPLICATIONS

The present application claims priority to Japanese Patent Application No. 2016-194456 (filed on Sep. 30, 2016). The content of the application is incorporated herein by reference in its entirety.

### TECHNICAL FIELD

The present disclosure relates to a light-emitting device and a method of producing a light-emitting device.

### BACKGROUND

Light-emitting devices using light-emitting elements including light-emitting diodes (LEDs) are now being widely used in various fields such as of illumination. Known examples of light-emitting devices using LEDs include one having a structure in which LEDs are placed on a substrate and the LEDs and the substrate are sealed with a resin composition composed of a phosphor contained in a resin such as a silicone resin. Also known are light-emitting devices in which LEDs are placed on a reflector made of a silver plate or a silver-plated plate thereby improving light extraction efficiency.

When a sulfide-based phosphor is used as a phosphor in such a light-emitting device, the sulfide-based phosphor, which readily reacts with water, can for example react with moisture in the atmosphere, so that sulfur-based gas such as hydrogen sulfide, sulfur dioxide, or sulfur trioxide may be generated. The generation of sulfur-based gas would lead to corrosion of a reflector and other members having silver on their surfaces, which is a cause of deterioration in the reflection performance of the reflector and hence deterioration of light-emission characteristics and electrical faults such as disconnection.

With a view to addressing these problems, for example, PTL 1 discloses that a sulfide-based phosphor coated with a silicon dioxide film containing metal oxide powder can be used as a phosphor to adsorb sulfur-based gas released from the sulfide-based phosphor to the metal oxide powder thereby suppressing the release of the sulfur-based gas.

### CITATION LIST

### Patent Literature

PTL 1: JP 2013-119581 A

### SUMMARY

### Technical Problem

However, the conventional technique described above is focused on improving the phosphor used itself, and improvement of a light-emitting device itself using a sulfide-based phosphor has not yet been fully discussed.

The present disclosure is directed at solving the conventional problems described above and achieving the following objectives. Specifically, it could be helpful to provide a method of providing a light-emitting device excellent in light-emission characteristics, for which deterioration of performance such as deterioration of light-emission characteristics due to generation of sulfur-based gas is sufficiently suppressed, and a simple method of producing the light-emitting device.

### Solution to Problem

The inventors of this disclosure have made intensive studies to achieve the above objective and found, as a result, that deterioration of performance such as deterioration of light-emission characteristics due to generation of sulfur-based gas can be sufficiently suppressed by at least optimizing the structure of a layer made of a resin composition for encapsulating a light-emitting element such as an LED.

The present disclosure is based on the inventors' findings mentioned above and provides the following features to solve the problems described above.

<1> A light-emitting device comprising:

a light-emitting element;

one or more silver-based members having silver on their surfaces; and

a resin layer including a first resin layer covering at least one of the silver-based members, and a second resin layer placed directly on the first resin layer,

wherein the light-emitting element is covered with the first resin layer or both the first resin layer and the second resin layer,

at least one of the first resin layer and the second resin layer contains an inorganic adsorbent which chemically adsorbs a sulfide,

the second resin layer contains a sulfide-based phosphor, and

a ratio of a thickness of the first resin layer with respect to a total thickness of the first resin layer and the second resin layer is 50% or more.

<2> The light-emitting device according to <1> above, wherein one of the first resin layer and the second resin layer which covers the light-emitting element contains the inorganic adsorbent.

<3> The light-emitting device according to <1> or <2> above, wherein the thickness of the first resin layer is 240 μm or more.

<4> The light-emitting device according to any one of <1> to <3> above, wherein the inorganic adsorbent includes particles formed from a compound containing a metal element.

<5> The light-emitting device according to <4> above, wherein the compound containing the metal element is selected from MgO, CaO, BaO, BaB₂O₄, SrO, La₂O₃, ZnO, Zn(OH)₂, ZnSO₄.nH₂O (0≤n≤7), ZnTi₂O₄, Zn₂Ti₃O₈, Zn₂TiO₄, ZnTiO₃, ZnBaO₂, ZnBa₂O₃, ZnGa₂O₄, Zn_{1.23}Ga_{0.28}O₂, Zn₃GaO₄, Zn₆Ga₂O₉, Zn_{0.125-0.95}Mg_{0.05-0.9}O, Zn_{0.1-0.75}Ca_{0.25-0.9}O, ZnSrO₂, Zn_{0.3}Al_{2.4}O₄, ZnAl₂O₄, Zn₃₋₇In₂O₆₋₁₀, ZnSnO₃, Zn₂SnO₄; and silicates containing a metal element selected from Cu, Zn, Mn, Co, Ni, Zr, Al, and lanthanide elements.

<6> The light-emitting device according to <4> above, wherein the compound containing the metal element is ZnO.

<7> The light-emitting device according to any one of <1> to <6> above, wherein the first resin layer and the second resin layer contain one of a silicone resin and an epoxy resin.

<8> The light-emitting device according to any one of <1> to <7> above, wherein the resin layer contains glass flakes.

<9> The light-emitting device according to any one of <1> to <8> above, wherein one of the layers that compose the resin layer, which is farthest from the silver-based member covered with the first resin layer contains glass flakes.

<10> The light-emitting device according to any one of <1> to <9> above, wherein the sulfide-based phosphor includes a green phosphor represented by MGa₂S₄:Eu (M represents one or more elements including at least one of Sr, Ba, and Ca).

<11> The light-emitting device according to any one of <1> to <9> above, wherein the sulfide-based phosphor includes a green phosphor represented by SrGa₂S₄:Eu.

<12> The light-emitting device according to any one of <1> to <11> above, wherein the sulfide-based phosphor has, on its surface, a coating film including a first silicon dioxide film and a second silicon dioxide film on the first silicon dioxide, and at least one of the first silicon dioxide film and the second silicon dioxide film contains metal oxide powder.

<13> The light-emitting device according to <12> above, wherein an outermost film of the silicon dioxide films that compose the coating film contains metal oxide powder.

<14> The light-emitting device according to <12> or <13> above, wherein the metal oxide powder contains zinc oxide powder.

<15> A method of producing the light-emitting device according to any one of <1> to <14> above, comprising:

a step of preparing a reflector having silver on its surface, with a light-emitting element being provided on the reflector;

a step of forming a first resin layer by supplying a first resin composition so as to cover the reflector; and

a step of forming a second resin layer by supplying a second resin composition directly onto the first resin layer,

wherein at least one of the first resin composition and the second resin composition contains an inorganic adsorbent which chemically adsorbs a sulfide,

the second resin composition contains a sulfide-based phosphor, and

an amount of the first resin composition supplied and an amount of the second resin composition supplied are determined so that a ratio of a thickness of the first resin layer to be formed with respect to a total thickness of the first resin layer and the second resin layer to be formed will be 50% or more.

### Advantageous Effect

The present disclosure solves the existing problems described above and provides a method of providing a light-emitting device excellent in light-emission characteristics, for which deterioration of performance such as deterioration of light-emission characteristics due to generation of sulfur-based gas is sufficiently suppressed, and a simple method of producing the light-emitting device.

### BRIEF DESCRIPTION OF THE DRAWINGS

In the accompanying drawings:

FIG. 1 is a schematic view of a light-emitting device according to one embodiment of the present disclosure;

FIG. 2 is a schematic view of a light-emitting device according to another embodiment of the present disclosure;

FIG. 3 is a schematic cross-sectional view of a light-emitting device according to yet another embodiment of the present disclosure;

FIG. 4 is a schematic cross-sectional view of a sulfide-based phosphor according to one embodiment, which phosphor can be included in a light-emitting device of the present disclosure;

FIG. 5 is a schematic cross-sectional view of a sulfide-based phosphor according to another embodiment, which phosphor can be included in a light-emitting device of the present disclosure; and

FIG. 6 is a schematic cross-sectional view of a sulfide-based phosphor according to yet another embodiment, which phosphor can be included in a light-emitting device of the present disclosure.

### DETAILED DESCRIPTION

(Light-Emitting Device)

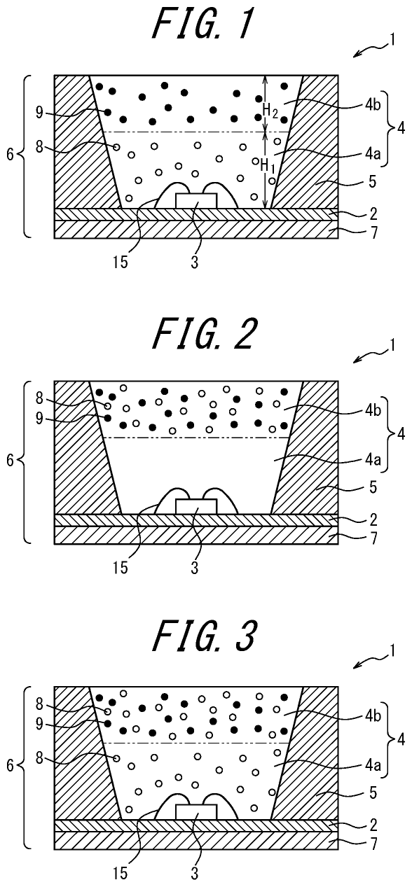

The following uses FIG. 1 and so forth to describe a light-emitting device 1 according to one embodiment of the present disclosure.

A light-emitting device 1 according to one embodiment of the present disclosure (hereinafter also simply referred to as a “presently disclosed light-emitting device”) includes at least a reflector 2, a light-emitting element 3 placed on the reflector 2, and a resin layer 4. The resin layer 4 includes a first resin layer 4a and a second resin layer 4b placed directly on the first resin layer 4a.

The reflector 2 is not particularly limited, and may compose a lead frame 6 with a resin layer accommodation member 5 as illustrated in FIGS. 1 to 3.

Further, the presently disclosed light-emitting device 1 may include a substrate 7 as a component of the lead frame 6 under the reflector 2 as illustrated in FIGS. 1 to 3, and may also include other optional components.

<Substrate>

The substrate 7 can be appropriately selected depending on the purpose without any specific limitations. The substrate 7 can be a plate-like substrate that is known in the technical field of light-emitting devices such as a ceramic substrate, a resin substrate, a metal substrate, or a glass epoxy substrate.

<Resin Layer Accommodation Member>

The resin layer accommodation member 5 is not particularly limited and is a member having a structure in which an open region opens for example in a circular shape on the upper surface and the lower surface, and the resin layer accommodation member 5 can form a space in which the resin layer 4 is contained with the reflector 2 being placed under the lower surface. In order to increase the light extraction efficiency of the light-emitting device 1, preferably the diameter of the opening on the upper surface of the resin layer accommodation member 5 is larger than the opening on the lower surface and a cross section (walls) of the open region is inclined, as depicted in FIG. 1.

The resin layer accommodation member 5 may be formed using for example a composition containing a thermosetting resin by a method such as injection molding.

<Reflector>

The reflector 2 is a plate-like reflector for reflecting light emitted from the light-emitting element 3 toward the surface (upper part) of the light-emitting device 1. The reflector 2 usually has silver on its surface. Further, the entire surface of the reflector 2 (specifically, the entire surface that can be visually observed through the open region of the resin layer accommodation member 5) is covered with the first resin layer 4a.

Note that the reflector 2 having silver on its surface may be a flat plate made of silver, or may be a given flat plate-like substrate with is silver plated.

<Light-Emitting Element>

The light-emitting element 3 is typically placed on the reflector 2, and is covered with (encapsulated with) the first resin layer 4a as illustrated in FIGS. 1 to 3 or is covered with (encapsulated with) both the first resin layer 4a and the second resin layer 4b. Here, in FIG. 1, the light-emitting element 3 is directly mounted on the reflector 2 with a metal wire 15 using chip on board (COB) techniques; however, the mounting technique is not limited thereto.

For example, the metal wire 15 may have silver on its surface. Accordingly, when a wire having silver on its surface is used as the metal wire 15, the metal wire 15 can be covered with the first resin layer 4a as depicted in FIG. 1.

Considering that the light-emitting element 3 can also have silver on its surface, the light-emitting element 3 is preferably covered with the first resin layer 4a as illustrated in FIG. 1 in terms of suppressing silver corrosion caused by sulfur-based gas.

The light-emitting element 3 can be appropriately selected depending on the purpose without any specific limitations and is for example a light-emitting diode. In a situation in which a light-emitting diode is used as the light-emitting element 3, the light-emitting diode can for example be, but not limited to, a blue light-emitting diode. Here, the blue light-emitting diode is a light-emitting diode that uses gallium nitride (GaN) as a main material and that emits light of a blue color.

<Resin Layer>

The resin layer 4 includes at least the first resin layer 4a and the second resin layer 4b placed directly on the first resin layer 4a and covers (to encapsulate) the light-emitting element 3. Further, the first resin layer 4a covers at least one member having silver on its surface. Specifically, for example when the reflector 2 has silver on its surface, the first resin layer 4a may cover at least the reflector 2 as illustrated in FIG. 1, and for example when the metal wire 15 has silver on its surface, the first resin layer 4a may cover at least the metal wire 15 as illustrated in FIG. 1. This can suppress silver corrosion caused by sulfur-based gas which can be released from a sulfide-based phosphor 9, which can maintain good performance of the light-emitting device, for example, good light-emission characteristics.

Further, the second resin layer 4b of the resin layer 4 is required to contain the sulfide-based phosphor 9. Thus, the lead frame 6 etc. is filled with a plurality of layers of resin and the sulfide-based phosphor 9 is contained in the second resin layer 4b, thereby maintaining good performance of the light-emitting device, for example, good light-emission characteristics by keeping a distance between the sulfide-based phosphor 9 and the light-emitting element 3 to suppress thermal degradation of the sulfide-based phosphor 9. From the same perspective, the first resin layer 4a of the resin layer 4 preferably does not contain the sulfide-based phosphor 9.

Note that the first resin layer 4a and/or the second resin layer 4b of the resin layer 4 may contain a phosphor other than the sulfide-based phosphor to obtain desired light.

Further, the resin layer 4 may be composed of only the first resin layer 4a and the second resin layer 4b as illustrated in FIG. 1, or may further include an optional resin layer.

Moreover, the resin layer 4 may fill the space in the resin layer accommodation member 5 up to the top surface of the resin layer accommodation member 5 as illustrated in FIG. 1, or may for example be swollen up like a dome.

The resin layer 4 including the first resin layer 4a and the second resin layer 4b is mainly formed from a transparent resin; for example, the first resin layer 4a and the second resin layer 4b preferably contain a silicone resin such as a phenyl silicone resin or a methyl silicone resin, or an epoxy resin. For the transparent resin, a transparent resin may be used alone, or two or more transparent resins may be used in combination.

For the resin layer 4, the ratio of the thickness of the first resin layer 4a with respect to the total thickness of the first resin layer 4a and the second resin layer 4b (H₁/(H₁+H₂)×100 in FIG. 1) needs to be 50% or more. The inventors found that when the above ratio is 50% or more, the sulfide-based phosphor 9 contained in the second resin layer 4b can be suitably distant from a silver-based member such as the reflector 2, and thus corrosion of the silver-based member, caused by sulfur-based gas which can be released from the sulfide-based phosphor 9 can be suppressed. When the above ratio is less than 50%, corrosion of the silver-based member covered by the first resin layer 4a cannot sufficiently be suppressed, so that good performance of the light-emitting device, for example, good light-emission characteristics cannot be ensured.

Further, in terms of more effectively suppressing corrosion of the silver-based member such as the reflector 2, caused by sulfur-based gas which can be released from the sulfide-based phosphor 9, the ratio of the thickness of the first resin layer 4a with respect to the total thickness of the first resin layer 4a and the second resin layer 4b is preferably 60% or more, more preferably, 70% or more.

Note that the thickness of the first resin layer 4a, the thickness of the second resin layer 4b, and the total thickness of the first resin layer 4a and the second resin layer 4b refer to the thicknesses in direction perpendicular to surfaces of the substrate 7 and the reflector 2, and when the above thicknesses are not uniform, the thicknesses refer to the thicknesses of the thinnest portions.

The thickness of the first resin layer 4a of the resin layer 4 (H₁ in FIG. 1) is preferably 240 μm or more. This ensures that the sulfide-based phosphor 9 contained in the second resin layer 4b is distant from the silver-based member such as the reflector 2, thus corrosion of the silver-based member, caused by sulfur-based gas which can be released from the sulfide-based phosphor 9 can be more reliably suppressed. From the same perspective, the thickness of the first resin layer 4a in the resin layer 4 is preferably 300 μm or more, more preferably 350 μm or more.

Note that the total thickness of the resin layer 4 may preferably be, but not limited to, 250 μm or more, more preferably 450 μm or more, and preferably 750 μm or less, more preferably 550 μm or less.

—Sulfide-Based Phosphor—

As the sulfide-based phosphor 9, any phosphor containing sulfur can be appropriately selected depending on the purpose without any specific limitations, and the phosphor preferably contains a green phosphor represented by MGa₂S₄:Eu (M denotes one or more elements containing at least one of Sr, Ba, and Ca). Of sulfide-based phosphors, the above green phosphor is a phosphor which relatively readily produces sulfur-based gas upon reaction (hydrolysis degradation) with moisture in the atmosphere; however, in the presently disclosed light-emitting device, even when the above green phosphor is used as the sulfide-based phosphor 9, an inorganic adsorbent 8 suitably adsorbs sulfur-based gas to suppress corrosion of the silver-based member such as the reflector 2. From the same perspective, as the green phosphor represented by the above chemical formula, a green phosphor containing M denoting (an) element(s) consisting only of at least one of Sr, Ba, and Ca is preferred, and a green phosphor represented by SrGa₂S₄:Eu is more preferred.

For the sulfide-based phosphor 9, one phosphor may be used alone, or two or more phosphors may be used in combination.

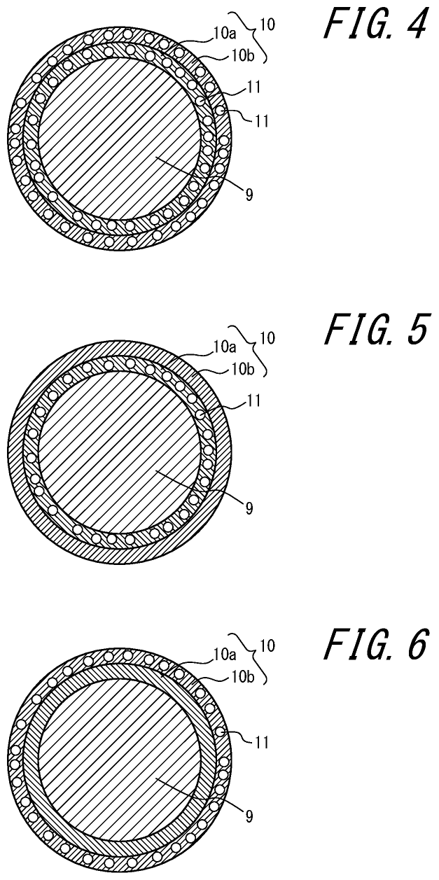

Further, the sulfide-based phosphor 9 has a coating 10 including a first silicon dioxide film 10a and a second silicon dioxide film 10b on the first silicon dioxide film 10a as illustrated in FIGS. 4 to 6, and at least one of the first silicon dioxide film 10a and the second silicon dioxide film 10b preferably contains metal oxide powder 11 (such a sulfide-based phosphor is hereinafter also referred to as a “coated sulfur-based phosphor”). Thus, the sulfide-based phosphor 9 is prevented from being exposed to moisture in the atmosphere to suppress degradation of the sulfide-based phosphor 9, whereas even when the sulfide-based phosphor 9 reacts with water to produce sulfur-based gas, the metal oxide powder 11 contained in the silicon dioxide film coating the sulfide-based phosphor 9 adsorbs the sulfur-based gas, thus the amount of the sulfur-based gas itself can be reduced.

In particular, in terms of effectively suppressing the release of sulfur-based gas from the sulfide-based phosphor 9, the outermost film of the silicon dioxide films that compose the coating film 10 preferably contains the metal oxide powder 11. Specifically, for example when the coating film 10 is composed only of the first silicon dioxide film 10a and the second silicon dioxide film 10b, the second silicon dioxide film 10b that is the outermost silicon dioxide film preferably contains the metal oxide powder 11 as illustrated in FIG. 4 and FIG. 6. Alternatively, for example when the coating film 10 includes, in addition to the first silicon dioxide film 10a and the second silicon dioxide film 10b, a third silicon dioxide film (not shown) on the second silicon dioxide film 10b, the third silicon dioxide film that is the outermost silicon dioxide film preferably contains the metal oxide powder 11.

Note that the silicon dioxide films may be formed for example by hydrolysis of alkoxysilane (sol-gel process).

As the metal oxide powder 11, powder having a superior adsorption capacity for sulfur-based gas, such as, for example, hydrogen sulfide, and capable of suppressing the generation of sulfur-based gas is preferably used. Examples of the metal oxide powder 11 include zinc oxide (ZnO) powder and aluminum oxide (Al₂O₃) powder, and in particular, from the viewpoint of more effectively suppressing the generation of sulfur-based gas, the metal oxide powder 11 preferably contains zinc oxide (ZnO) powder. Here, the metal oxide powder 11 may be powder having been subjected to a surface treatment.

For the metal oxide powder 11, one kind of powder may be used alone, or two or more kinds of powder may be used in combination.

The metal oxide powder 11 preferably has a particle diameter of 0.2 μm or less. By setting the particle diameter of the metal oxide powder 11 to 0.2 μm or less, the adsorption capacity of the metal oxide powder 11 for the sulfur-based gas is prevented from being lowered, and thus the release of the sulfur-based gas from the sulfide-based phosphor 9 can effectively be suppressed.

The amount of the metal oxide powder 11 is preferably set to 1 part by mass or more and less than 20 parts by mass relative to 100 parts by mass of the sulfide-based phosphor 9, more preferably 5 parts by mass or more and 10 parts by mass or less. By setting the amount of the metal oxide powder 11 to 1 part by mass or more relative to the 100 parts by mass of the sulfide-based phosphor 9, the metal oxide powder 11 can have an effective adsorbing function, that is, the adsorption capacity of the metal oxide powder 11 for the sulfur-based gas can be prevented from being lowered. Moreover, by setting the amount of the metal oxide powder 11 to less than 20 parts by mass relative to the 100 parts by mass of the sulfide-based phosphor 9, deterioration of the characteristics of the sulfide-based phosphor 9, such as, for example, reduction in the peak intensity and luminance can be suppressed.

Although the content of the sulfide-based phosphor 9 in the second resin layer 4b may be appropriately selected depending on the purpose without any specific limitations, the content is preferably 3 mass % or more with respect to the resin in terms of obtaining desired light-emission characteristics, whereas the content is preferably 10 mass % or less in terms of preventing excessive generation of sulfur-based gas.

—Inorganic Adsorbent—

For the resin layer 4, at least one of the first resin layer 4a and the second resin layer 4b is required to contain the inorganic adsorbent 8 which chemically adsorbs sulfides. When at least one of the first resin layer 4a and the second resin layer 4b contains the inorganic adsorbent 8, even if the sulfide-based phosphor 9 contained in the second resin layer 4b produces sulfur-based gas upon reaction with moisture in the atmosphere, the inorganic adsorbent 8 adsorbs the sulfur-based gas, thus corrosion of the silver-based member such as the reflector 2 can be suppressed.

The inorganic adsorbent 8 may be present only in the first resin layer 4a of the resin layer 4 as illustrated in FIG. 1, may be present only in the second resin layer 4b of the resin layer 4 as illustrated in FIG. 2, or may be present in both the first resin layer 4a and the second resin layer 4b as illustrated in FIG. 3.

More preferably, as depicted in FIG. 1, only the first resin layer 4a in the resin layer 4 contains the inorganic adsorbent 8. Thus, the inorganic adsorbent 8 is not present in the same layer as the sulfide-based phosphor 9, so that the inorganic adsorbent 8 can adsorb only the sulfur-based gas that has reached the lower layer through the upper layer. Accordingly, the adsorption capacity of the inorganic adsorbent 8 can be made to last longer compared with the case where the inorganic adsorbent 8 is present in the same layer as the sulfide-based phosphor 9, which more effectively suppresses corrosion of the silver-based member such as the reflector 2.

On the other hand, in terms of the positional relationship between the resin layer 4 and the light-emitting element 3, one of the first resin layer 4a and the second resin layer 4b which covers the light-emitting element 3 preferably contains the inorganic adsorbent 8. Specifically, when the first resin layer 4a covers (to encapsulate) the light-emitting element 3 in addition to the silver-based member such as the reflector 2, and the second resin layer 4b is not in contact with the light-emitting element 3; the first resin layer 4a preferably contains the inorganic adsorbent 8. Whereas when the first resin layer 4a does not completely cover the light-emitting element 3, and the light-emitting element 3 is covered (encapsulated) with the first resin layer 4a and the second resin layer 4b; both the first resin layer 4a and the second resin layer 4b preferably contain the adsorbent 8. Typically, heat and light has a great influence around the light-emitting element 3 and there is thus a tendency that the reaction of moisture with the sulfide-based phosphor 9 is accelerated to significantly produce sulfur-based gas such as hydrogen sulfide; however, the above structure can effectively suppress generation of sulfur-based gas around the light-emitting element 3.

The inorganic adsorbent 8 is not particularly limited as long as it is an inorganic material that can chemically adsorb a sulfide, for example, adsorbs a sulfide by coordinate bonds, however, in terms of achieving higher adsorption capacity, the inorganic adsorbent 8 preferably contains particles formed from a compound containing a metal element.

For the inorganic adsorbent 8, one inorganic adsorbent may be used alone, or two or more inorganic adsorbents may be used in combination.

Here, the compound containing the metal element is not particularly limited, and may be selected, depending on the purpose, from for example MgO, CaO, BaO, BaB₂O₄, SrO, La₂O₃, ZnO, Zn(OH)₂, ZnSO₄.nH₂O (0≤n≤7), ZnTi₂O₄, Zn₂Ti₃O₈, Zn₂TiO₄, ZnTiO₃, ZnBaO₂, ZnBa₂O₃, ZnGa₂O₄, Zn_{1.23}Ga_{0.28}O₂, Zn₃GaO₄, Zn₆Ga₂O₉, Zn_{0.125-0.95}Mg_{0.05-0.9}O, Zn_{0.1-0.75}Ca_{0.25-0.9}O, ZnSrO₂, Zn_{0.3}Al_{2.4}O₄, ZnAl₂O₄, Zn₃₋₇In₂O₆₋₁₀, ZnSnO₃, Zn₂SnO₄; and silicates containing a metal element selected from Cu, Zn, Mn, Co, Ni, Zr, Al, and lanthanide elements. For the compound containing the metal element, one compound may be used alone, or two or more compounds may be used in combination.

In particular, in terms of achieving even higher adsorption capacity, the inorganic adsorbent 8 more preferably contains particles formed from ZnO.

For the above-mentioned silicates containing a metal element, the molar ratio of the metal and silicon is preferably metal/silicon=0.60-0.80. Such silicates can be produced by reacting a metal salt with an alkali silicate. Further, for the above metal salt, an inorganic salt such as sulfuric acid, hydrochloric acid, nitric acid, etc., and/or an organic salt such as formic acid, acetic acid, or oxalic acid of at least one metal selected from copper, zinc, manganese, cobalt, nickel, zirconium, aluminum, and lanthanides can be used. In particular, the metal is preferably copper(I), copper(II), or zinc(I). Examples of the above silicates containing a metal element include an alkali silicate represented by M₂O.nSiO₂.xH₂O (M denotes a monovalent alkali metal, n is equal to or more than 1, x is equal to or more than 0).

The content of the inorganic adsorbent 8 in the first resin layer 4a and/or the second resin layer 4b is not particularly limited and can be appropriately selected depending on the purpose; however, in terms of allowing sulfur-based gas to be effectively adsorbed using the minimum amount of the adsorbent required, the content is preferably a ratio of 1% by mass or more and 5% by mass or less relative to the resin.

—Glass Flakes—

Further, the resin layer 4 preferably contains glass flakes (not shown). When the resin layer 4 contains glass flakes, the glass flakes serve as a diffusion barrier for water in the atmosphere, which can suppress generation of sulfur-based gas upon reaction of the sulfide-based phosphor 9 with water and therefore can suppress corrosion of the silver-based member such as the reflector 2, caused by the sulfur-based gas.

From the same point of view, one of the layers that compose the resin layer 4 which is most distant from the silver-based member such as the reflector 2 preferably contains glass flakes. Specifically, for example when the resin layer 4 is composed only of the first resin layer 4a and the second resin layer 4b, the second resin layer 4b that is the layer most distant from the silver-based member such as the reflector 2 covered with the first resin layer 4a preferably contains glass flakes. Alternatively, for example when the resin layer 4 includes a third resin layer (not shown) directly on the second resin layer 4b in addition to the first resin layer 4a and the second resin layer 4b, the third resin layer that is the layer most distant from the silver-based member such as the reflector 2 covered with the first resin layer 4a preferably contains glass flakes.

In terms of achieving more effective diffusion barrier effects for water in the atmosphere, the glass flakes preferably have a diameter of 5 μm or more and 20 μm or less and a thickness of 0.1 μm or more and 5 μm or less.

Further, the content of the glass flakes in the resin layer is not particularly limited and can be appropriately selected depending on the purpose; however, in terms of achieving more effective diffusion barrier effects for water in the atmosphere, the content preferably has a ratio of 1% by mass or more and 5% by mass or less relative to the resin.

(Light-Emitting Device Production Method)

The following describes a method of producing a light-emitting device according to one embodiment of the present disclosure that enables production of the presently disclosed light-emitting device described above. Note that specific features of members and materials in the light-emitting device production method according to one embodiment of the present disclosure are the same as those previously described for the presently disclosed light-emitting device.

The method of producing a light-emitting device according to one embodiment of the present disclosure includes a reflector preparation step; a first resin layer formation step; and a second resin layer formation step, and the method may further includes other steps such as a phosphor preparation step; a coated phosphor preparation step; a resin composition preparation step; and an additional resin layer formation step, as necessary.

<Reflector Preparation Step>

The reflector preparation step is a step of preparing the reflector 2 having silver on its surface, with the light-emitting element 3 being provided on the reflector. In the step of preparing a reflector, for example, a reflector may be prepared in such a manner that the light-emitting device 3 is mounted on the lead frame 6 provided with the reflector 2 and the resin layer accommodation member 5.

Note that without particular limitation, the relationship between the amount of the resin composition filling the lead frame 6 and the height of the resin layer formed by filling the lead frame 6 with the forgoing amount of the resin composition is preferably ascertained in advance.

<Phosphor Preparation Step>

The phosphor preparation step is a step of preparing the sulfide-based phosphor to be contained in the second resin layer 4b. In this step, for example, a green phosphor represented by MGa₂S₄:Eu (M represents one or more elements including at least one of Sr, Ba, and Ca) can be prepared. In preparing the green phosphor according to one embodiment, a mixed solution of a europium compound and at least one of a strontium compound, a calcium compound, and a barium compound is poured into a sulfite solution to which a gallium compound powder is added, thereby obtaining a powder mixture of a sulfite containing Eu, Ga, and at least one of Sr, Ca, and Ba. After that, the powder mixture can be fired to obtain the green phosphor represented by MGa₂S₄:Eu (M denotes one or more elements including at least one of Sr, Ba, and Ca). Accordingly, in the step of preparing the green phosphor according to one embodiment, a wet process can be used in which a starting material is formed in a liquid phase.

Examples of the europium compound used include europium nitrates [Eu(NO₃)₃.xH₂O], europium oxalates [Eu₂(C₂O₄)₃.xH₂O], europium carbonates [Eu₂(CO₃)₃.xH₂O], europium sulfate [Eu₂(SO₄)₃], europium chlorides [EuCl₃.xH₂O], europium fluoride [EuF₃], europium hydrides [EuHₓ], europium sulfide [EuS], europium tri-i-propoxide [Eu(O-i-C₃H₇)₃], and europium acetate [Eu(O—CO—CH₃)₃].

For the europium compound, one europium compound may be used alone, or two or more europium compounds may be used in combination.

Examples of the strontium compound used include strontium nitrate [Sr(NO₃)₂], strontium oxide [SrO], strontium bromides [SrBr₂.xH₂O], strontium chlorides [SrCl₂.xH₂O], strontium carbonate [SrCO₃], strontium oxalate [SrC₂O₄.H₂O], strontium fluoride [SrF₂], strontium iodides [SrI₂.xH₂O], strontium sulfate [SrSO₄], strontium hydroxides [Sr(OH)₂.xH₂O], and strontium sulfide [SrS].

For the strontium compound, one strontium compound may be used alone, or two or more strontium compounds may be used in combination.

Examples of the calcium compound used include calcium nitrate [Ca(NO₃)₂], calcium oxide [CaO], calcium bromides [CaBr₂.xH₂O], calcium chlorides [CaCl₂.xH₂O], calcium carbonate [CaCO₃], calcium oxalate [CaC₂O₄.H₂O], calcium fluoride [CaF₂], calcium iodides [CaI₂.xH₂O], calcium sulfate [CaSO₄], calcium hydroxide [Ca(OH)₂], and calcium sulfide [CaS].

For the calcium compound, one calcium compound may be used alone, or two or more compounds may be used in combination.

Examples of the barium compound used include barium nitrate [Ba(NO₃)₂], barium oxide [BaO], barium bromides [BaBr₂.xH₂O], barium chlorides [BaCl₂.xH₂O], barium carbonate [BaCO₃], barium oxalate [BaC₂O₄.H₂O], barium fluoride [BaF₂], barium iodides [BaI₂.xH₂O], barium sulfate [BaSO₄], barium hydroxide [Ba(OH)₂], and calcium sulfide [BaS].

For the barium compound, one barium compound may be used alone, or two or more barium compounds may be used in combination.

As a solvent for obtaining the above mixed solution, purified water, an aqueous nitric acid solution, an aqueous ammonia solution, an aqueous hydrochloric acid solution, an aqueous sodium hydroxide solution, or a mixed aqueous solution of those solutions can be used.

Further, examples of the gallium compound powder used include gallium oxide [Ga₂O₃], gallium sulfates [Ga₂(SO₄)₃.xH₂O], gallium nitrates [Ga(NO₃)₃.xH₂O], gallium bromide [GaBr₃], gallium chloride [GaCl₃], gallium iodide [GaI₃], gallium(II) sulfide [GaS], gallium(III) sulfide [Ga₂S₃], and gallium oxyhydroxide [GaOOH].

For the gallium compound, one gallium compound may be used alone, or two or more gallium compounds may be used in combination.

As the sulfite to which the powder gallium compound is added, ammonium sulfite, sodium sulfite, or potassium sulfite can be used.

Further, without limitation to the above-mentioned operation, the green phosphor represented by MGa₂S₄:Eu (M denotes one or more elements including at least one of Sr, Ba, and Ca) may be obtained by adding gallium compound powder to a mixed solution containing the europium compound and at least one of the strontium compound, calcium compound, and barium compound, and pouring the mixed solution containing Eu, Ga, and at least one of Sr, Ca, and Ba into a sulfite solution, thereby obtaining a powder mixture of the sulfite containing Eu, Ga, and at least one of Sr, Ca, and Ba, followed by firing of the powder mixture.

<Coated Phosphor Preparation Step>

The coated phosphor preparation step is a step of obtaining a coated sulfide-based phosphor by forming on the sulfide-based phosphor 9, the coating film 10 including the first silicon dioxide film 10a and the second silicon dioxide film 10b on the first silicon dioxide film 10a. In this step, for example, a mixed solution is prepared by mixing the sulfide-based phosphor 9, alkoxysilane, the metal oxide powder 11, and a catalyst in a solvent to coat the sulfide-based phosphor 9 with a silicon dioxide film formed from alkoxysilane containing the metal oxide powder 11, and the above mixed solution is then separated into a solid phase and a liquid phase, thus the silicon dioxide film (10a or 10b) containing the metal oxide powder 11 can be formed on the surface of the sulfide-based phosphor 9. Accordingly, in order to form the first silicon dioxide film 10a and the second silicon dioxide film 10b, the operation described above can be repeated once. Further, in order to form an additional silicon dioxide film, the above operation can be repeated once more.

Note that when the silicon dioxide film (10a or 10b) which does not contain the metal oxide powder 11 is formed, simply the metal oxide powder 11 is not used in the above step.

The alkoxysilane may be selected from ethoxides, methoxides, isopropoxides, and the like, and examples thereof include tetraethoxysilane and tetramethoxysilane. Moreover, the alkoxysilane may be an alkoxysilane oligomer or a hydrolytic condensate, such as polyethyl silicate. Furthermore, as the alkoxysilane, a silane coupling agent having an alkyl group, an amino group, a mercapto group, or the like, which does not contribute to a sol-gel reaction, such as alkyl alkoxysilane, may be used.

For the alkoxysilane, one type of alkoxysilane may be used alone, or two or more types of alkoxysilanes may be used in combination.

The solvent is not particularly limited, and for example, water, an organic solvent, or the like may be used. Examples of the organic solvent used include alcohols, ether, ketones, and polyhydric alcohols. Examples of the alcohols to be used include methanol, ethanol, propanol, and pentanol. Examples of polyhydric alcohols to be used include ethylene glycol, propylene glycol, and diethylene glycol.

For the solvent, one type of solvent may be used alone, or two or more types of solvents may be used in combination.

The catalyst is used to initiate a hydrolytic or polycondensation reaction of alkoxysilane, and for example, an acidic catalyst or a basic catalyst can be used. Examples of the acidic catalyst include hydrochloric acid, sulfuric acid, boric acid, nitric acid, perchloric acid, tetrafluoroboric acid, hexafluoroarsenic acid, hydrobromic acid, acetic acid, oxalic acid, and methanesulfonic acid. Examples of the basic catalyst include hydroxides of alkali metal, such as sodium hydroxide, and ammonia. Of these catalysts, in terms of effectively preventing degradation of the sulfide-based phosphor 9, a basic catalyst is preferably used.

For the catalyst, one type of catalyst may be used alone, or two or more types of catalysts may be used in combination.

In the separation of the mixed solution into a solid phase and a liquid phase, for example, the mixed solution is separated into a solid phase and a liquid phase using a suction filter, the solid phase thus separated is dried, and a sample obtained after the drying process is pulverized and subjected to a firing process. In this way, the sulfide-based phosphor 9 can be coated with the silicon dioxide film (10a or 10b) containing the metal oxide powder 11.

The temperature for drying the separated solid phase is preferably 80° C. to 110° C., which may be changed depending on the solvent to be used. Moreover, the period of time for drying the separated solid phase is preferably 2 hours or more.

Further, the firing temperature is preferably 150° C. to 250° C., and the firing time is preferably 8 hours or more.

<Resin Composition Preparation Step>

The resin composition preparation step is a step of preparing a first resin composition used in the first resin layer formation step and a second resin composition used in the second resin layer formation step. In preparing the second resin composition, at least a required amount of the sulfide-based phosphor 9 is added. Further, in at least one of the preparation of the first resin composition and the preparation of the second resin composition, a required amount of the inorganic adsorbent 8 which chemically adsorbs sulfide is added. The first resin composition and the second resin composition can be prepared by mixing at least a transparent resin and essential ingredients such as the sulfide-based phosphor 9 and the inorganic adsorbent 8 optionally with additives, for example, a plasticizer, a pigment, an antioxidant, a heat stabilizer, a light stabilizer, a light diffusing material, an anti-settling material, a filler, and the like. The mixing method can be appropriately selected depending on the purpose without any specific limitations other than enabling uniform mixing and can for example be mixing by vacuum stirring, propeller stirring in a vacuum desiccator, or rotation stirring using centrifugal force of rotation/revolution.

Note that the preparation of the first resin composition and the preparation of the second resin composition are not necessarily performed simultaneously, and for example may be performed before the first resin layer formation step and the second resin layer formation step, respectively.

<First Resin Layer Formation Step>

The first resin layer formation step is a step of forming the first resin layer 4a by supplying the first resin composition to cover the reflector 2 as a silver-based member. Here, the supply of the first resin composition may for example be performed by potting. In the first resin layer formation step, the first resin composition supplied to cover the reflector 2 encapsulates part of or the whole of the light-emitting element 3.

Here, in the first resin layer formation step, the amount of the first resin composition to be supplied is required to be determined in order that the first resin layer 4a to be formed have a desired thickness, specifically, in order that the ratio of the thickness of the first resin layer 4a with respect to the total thickness of the first resin layer 4a and the second resin layer 4b to be formed be 50% or more. Note that the amount of the first resin composition can be controlled, for example, using an electronic balance.

In the first resin layer formation step, for example, the first resin layer 4a is preferably formed by curing or semi-curing the supplied first resin composition. Curing or semi-curing the first resin composition can prevent ingredients of the second resin composition to be supplied later from entering the first resin layer. Note that in terms of achieving suitable adhesion on a surface of the first resin layer to be formed, achieving a good contact with the second resin layer to be formed later, and thus preventing air from mixing into the interface between the first resin layer and the second resin layer; the supplied first resin composition is preferably semi-cured.

Here, for example when a silicone resin or an epoxy resin is used, the curing can be accomplished typically by heating at approximately 150° C. (for example 130° C. or more and 170° C. or less) for approximately 2 hours (for example 1.5 hours or more and 2.5 hours or less), and the semi-curing can be accomplished typically by heating at approximately 100° C. (for example 80° C. or more and 120° C. or less) for approximately 1 hour (for example, 45 min or more and 1.5 hours or less).

<Second Resin Layer Formation Step>

The second resin layer formation step is a step of forming the second resin layer 4b by supplying the second resin composition on the first resin layer 4a formed in the first resin layer formation step. Here, the supply of the second resin composition may for example be performed by potting. In the second resin layer formation step, the second resin layer 4b can be placed directly on the first resin layer 4a.

Here, in the second resin layer formation step, the amount of the second resin composition to be supplied is required to be determined in order that the second resin layer 4b to be formed directly on the first resin layer 4a have a desired thickness, specifically, in order that the ratio of the thickness of the first resin layer 4a with respect to the total thickness of the previously formed first resin layer 4a and the second resin layer 4b to be formed be 50% or more. Note that the amount of the second resin composition can be controlled, for example, using an electronic balance.

In the second resin layer formation step, for example, the second resin layer 4b can be formed by curing the supplied second resin composition.

<Additional Resin Layer Formation Step>

The additional resin layer formational step is an optional step of forming an additional layer by preparing a resin composition containing desired ingredients and supplying the resin composition onto the second resin layer 4b.

Note that the resin composition can be prepared by the same manner as the preparation of the second resin composition, and the additional resin layer can be formed by the same manner as the formation of the second resin layer 4b.

Thus, the light-emitting devices as depicted in FIGS. 1 to 3 can easily be completed by the second resin layer formation step or the additional resin layer formation step.

### EXAMPLES

The following provides a more specific explanation of the present disclosure using examples and comparative examples. However, the present disclosure is not limited to the following examples.

### Example 1

### <(Uncoated) Sulfide-Based Phosphor Preparation>

As raw materials, Ga₂O₃ (purity: 6N), Sr (NO₃)₂ (purity: 3N), and Eu (NO₃)₃.nH₂O (purity: 3N, n=6.00), and ammonium sulfite monohydrate were prepared. The weights of the raw materials were determined to obtain a phosphor represented by a chemical composition formula of Sr₁₋ₓGa₂S₄:Euₓ where x=0.10 (Eu concentration: 10 mol %) in a molar amount of 0.2. Specifically, the weight of an europium compound (Eu(NO₃)₃.nH₂O) was determined to be 8.921 g, and the weight of a strontium compound (Sr(NO₃)₂) was determined to be 38.093 g.

Subsequently, the weighed europium compound and strontium compound were added to 200 ml of pure water and were sufficiently stirred to leave no undissolved solute, thus a mixed solution containing Eu and Sr was obtained.

Next, 37.488 g of gallium compound powder (pulverized Ga₂O₃) was added to a solution in which ammonium sulfite (30.974 g) in a number of moles of 1.15 times the total number of moles of Eu and Sr was dissolved in 200 ml of pure water, and the resultant solution was sufficiently stirred, thus a sulfite mixed solution was prepared.

Into this sulfite mixed solution, the foregoing mixed solution containing Eu and Sr was poured, thus a precipitate/sediment was obtained. This precipitate/sediment was a mixture of the europium-strontium sulfite powder and gallium oxide powder.

The precipitate/sediment was washed with pure water and filtered to achieve a conductivity of 0.1 mS/cm or less, and dried at 120° C. for 6 hours. After that, the filtrate was allowed to pass through a metal mesh having a nominal opening size of 100 μM thus a powder mixture containing Eu, Sr, Ca, and Ga was obtained. This powder mixture is a mixture containing europium/strontium sulfite powder [powder of (Sr, Eu)SO₃] and gallium oxide powder.

Next, the powder mixture was fired in an electric furnace. The firing conditions included heating to 925° C. in 1.5 hours and then keeping 925° C. for 1.5 hours, followed by cooling to room temperature in 2 hours. During firing, hydrogen sulfide was flown into the electric furnace at a rate of 0.3 liter/minute. After that, the powder mixture was allowed to bass through a mesh having a nominal opening size of 25 μm to obtain particles of a sulfide-based phosphor represented by Sr₁₋ₓGa₂S₄:Euₓ (x=0.10).

Note that when the PL spectrum of the sulfide-based phosphor was measured, the PL peak appeared at a wavelength of 538 nm, the PL peak intensity was 3.13 (YAG ratio), and the half width was 46 nm. Further, when the conversion efficiency was calculated, the absorptance was 82.3%, the internal quantum efficiency was 65.4%, and the external quantum efficiency was 53.9%.

<Coated Sulfide-Based Phosphor Preparation>

First, a first formulation obtained by mixing 10 g of the resultant sulfide-based phosphor, 80 g of ethanol, 5 g of purified water, and 6 g of 28% ammonia water; and a second formulation obtained by mixing 5 g of tetraethoxysilane and 35 g of ethanol were prepared.

Subsequently, the first formulation was charged into a container made of a polyethylene resin, a magnetic stirrer was placed therein, and stirring was performed in a constant temperature oven at 40° C. for 10 minutes. After that, the second formulation was charged into this container. The stirring was performed for 3 hours from the point at which the charge of the second formulation was completed. After the completion of stirring, suction filtration was performed using a vacuum pump, a recovered sample was transferred to a beaker, and after having been washed with water or ethanol, the resulting sample was again filtered to recover a sample. The recovered sample was dried at 85° C. for 2 hours and then fired at 200° C. for 8 hours, thus a sulfide-based phosphor having a first silicon dioxide film was obtained.

Next, a third formulation obtained by mixing 10 g of the resultant sulfide-based phosphor having the first silicon dioxide film, 80 g of ethanol, 5 g of purified water, and 6 g of 28% ammonia water; and another formulation having the same composition as the second formulation were prepared.

Subsequently, a coating process was performed in the same manner as the above-mentioned coating process, except that the third formulation and 0.1 g of powder of zinc oxide (K-FRESH MZO, produced by TAYCA CORPORATION) having a particle diameter of 0.1 μm to 0.2 μm (one part by mass relative to 100 parts by mass of the sulfide-based phosphor) was charged instead of charging the first formulation, thus a coated sulfide-based phosphor as depicted in FIG. 6 was obtained.

<Light-Emitting Device Production>

A lead frame having a silver reflector on which a light-emitting diode is directly placed was prepared.

On the other hand, a silicone resin (“OE-6550” (Part A:Part B=1:1) produced by Dow Corning Toray Co., Ltd.) and 2% by mass of an inorganic adsorbent (zinc oxide “KESMON” (registered trademark in Japan, other countries, or both) produced by Toagosei Co., Ltd.) relative to the silicone resin were charged into a container, and stirring and defoaming were performed for 180 seconds each using a planetary mixer (“AR-250” produced by THINKY CORPORATION), thus a first resin composition was prepared. The above-described lead frame was filled with 5 mg of the first resin composition (supplied into the lead frame) so that the composition could cover the silver reflector and the blue light-emitting diode, and the first resin composition was semi-cured by being heated at 100° C. for 1 hour.

Further, a silicone resin (“OE-6550” (Part A:Part B=1:1) produced by Dow Corning Toray Co., Ltd.) and 5% by mass of the coated sulfide-based phosphor (in an amount corresponding to chromaticity coordinates (x,y)=(0.1958,0.2333)) relative to the silicone resin were charged into a container, and stirring and defoaming were performed for 180 seconds each using a planetary mixer (“AR-250” produced by THINKY CORPORATION), thus a second resin composition was prepared. Two milligrams of this second resin composition was charged (supplied) onto the semi-cured first resin composition described above, and was cured by being heated at 150° C. for 2 hours.

Note that the amount of the first resin composition supplied and the amount of the second resin composition supplied were amounts having previously been determined in order that the first resin layer and the second resin layer to be formed have a desired thickness, considering the structure of the lead frame.

Thus, a light-emitting device was obtained. Note that when the fabricated light-emitting device was cut in the middle and the cross section was observed under SEM, the interface between the first resin layer and the second resin layer was found to be approximately parallel to the plane of the silver reflector, and the thickness of the first resin layer was found to be 350 μm, whereas the thickness of the second resin layer was found to be 140 μm.

### Example 2

A light-emitting device was obtained in the same manner as in the production of the light-emitting device in Example 1, except that in the preparation of the second resin composition, in addition to 5% by mass of the sulfide-based phosphor relative to the silicone resin, 2% by mass of glass flakes (“RCF-015” produced by Nippon Sheet Glass Co., Ltd) relative to the silicone resin was further charged into the container.

### Example 3

A light-emitting device was obtained in the same manner as in the production of the light-emitting device in Example 1, except that the (uncoated) sulfide-based phosphor prepared in Example 1 was used instead of the coated sulfide-based phosphor.

### Example 4

A light-emitting device was obtained in the same manner as in the production of the light-emitting device in Example 3, except that in the preparation of the second resin composition, in addition to 5% by mass of the (uncoated) sulfide-based phosphor relative to the silicone resin, 2% by mass of an inorganic adsorbent (zinc oxide “KESMON” produced by Toagosei Co., Ltd.) relative to the silicone resin was further charged into the container.

### Example 5

A light-emitting device was obtained in the same manner as in the production of the light-emitting device in Example 1, except that in the preparation of the second resin composition, in addition to 5% by mass of the coated sulfide-based phosphor relative to the silicone resin, 2% by mass of an inorganic adsorbent (zinc oxide “KESMON” produced by Toagosei Co., Ltd.) relative to the silicone resin was further charged into the container.

### Example 6

A light-emitting device was obtained in the same manner as in the production of the light-emitting device in Example 5, except that in the preparation of the second resin composition, in addition to 5% by mass of the sulfide-based phosphor relative to the silicone resin and 2% by mass of the inorganic adsorbent relative to the silicone resin, 2% by mass of glass flakes (“RCF-015” produced by Nippon Sheet Glass Co., Ltd) relative to the silicone resin were further charged into the container.

### Example 7

A light-emitting device was obtained in the same manner as in the production of the light-emitting device in Example 5, except that in the preparation of the first resin composition, the inorganic adsorbent was not charged into the container.

### Comparative Example 1

A light-emitting device was obtained in the same manner as in Example 1 except that the production of the light-emitting device was performed as described below.

<Light-Emitting Device Production>

A lead frame having a silver reflector on which a light-emitting diode is directly placed was prepared.

On the other hand, a silicone resin (“OE-6550” (Part A:Part B=1:1) produced by Dow Corning Toray Co., Ltd.) and 2% by mass of the coated sulfide-based phosphor relative to the silicone resin were charged into a container, and stirring and defoaming were performed for 180 seconds each using a planetary mixer (“AR-250” produced by THINKY CORPORATION), thus a resin composition was prepared. The above-mentioned lead frame was filled with 7 mg of this resin composition so that the resin composition would cover the silver reflector and the blue light-emitting diode, and the resin composition was cured by being heated at 150° C. for 2 hours.

### Comparative Example 2

A light-emitting device was obtained in the same manner as in the production of the light-emitting device in Example 1, except that in the preparation of the first resin composition, the inorganic adsorbent was not charged into the container.

### Comparative Example 3

A light-emitting device was obtained in the same manner as in the production of the light-emitting device in Example 2, except that in the preparation of the first resin composition, the inorganic adsorbent was not charged into the container.

### Comparative Example 4

A light-emitting device was obtained in the same manner as in the production of the light-emitting device in Comparative Example 1, except that in the preparation of the resin composition, the (uncoated) sulfide-based phosphor prepared in Example 1 was used instead of the coated sulfide-based phosphor.

### Example 8

A light-emitting device having a first resin layer with a thickness of 280 μm and a second resin layer with a thickness of 210 μm was obtained in the same manner as in Example 1 except that the amount of the first resin composition charged was changed from 5 mg to 4 mg, and the amount of the second resin composition charged was changed from 2 mg to 3 mg.

### Example 9

A light-emitting device having a first resin layer with a thickness of 245 μm and a second resin layer with a thickness of 245 μm was obtained in the same manner as in Example 1 except that the amount of the first resin composition charged was changed from 5 mg to 3.5 mg, and the amount of the second resin composition charged was changed from 2 mg to 3.5 mg.

### Comparative Example 5

A light-emitting device having a first resin layer with a thickness of 210 μm and a second resin layer with a thickness of 280 μm was obtained in the same manner as in Example 1 except that the amount of the first resin composition charged was changed from 5 mg to 3 mg, and the amount of the second resin composition charged was changed from 2 mg to 4 mg.

(Silver Corrosion Test and Reflectance Measurement)

The light-emitting devices obtained in Examples and Comparative Examples were each attached to a slide glass with double-side tape and introduced in a closed bottle (glass weighing bottle having a capacity of 100 ml) and a glass cell filled with water was placed in the closed bottle to achieve a humidity of 100% RH. The closed bottle was closed with a cap and was then placed into an oven at 85° C., thus a silver corrosion test was performed. For the silver reflector of the light-emitting device which had not been placed into the oven and the light-emitting device which had been placed in the oven for 48 hours, the reflectance for light of 560 nm was measured, based on a white plate mainly containing barium sulfate, using a spectrofluorometer (“FP-6500” produced by JASCO Corporation) provided with an integrating sphere unit.

The results are given in Tables 1 and 2. Note that when the reflectance of the silver reflector in the light-emitting device having been placed in the oven for 48 hours was 60% or more, corrosion of the silver reflector was sufficiently suppressed, so that the light-emitting device can be used in practical applications.

TABLE 1

| | | Example 1 | Example 2 | Example 3 | Example 4 | Example 5 | Example 6 | Example 7 |
|---|---|---|---|---|---|---|---|---|
| Second resin layer | Ingredient other | Sulfur-based | Sulfur-based | Sulfur-based | Sulfur-based | Sulfur-based | Sulfur-based | Sulfur-based |
| | than Resin | phosphor | phosphor | phosphor | phosphor | phosphor | phosphor | phosphor |
| | | (Coated) | (Coated) | | Inorganic | (Coated) | (Coated) | (Coated) |
| | | | Glass flakes | | adsorbent | Inorganic | Inorganic adsorbent | Inorganic |
| | | | | | | adsorbent | Glass flakes | adsorbent |
| | Thickness [μm] | 140 | 140 | 140 | 140 | 140 | 140 | 140 |
| First resin layer | Ingredient other | Inorganic | Inorganic | Inorganic | Inorganic | Inorganic | Inorganic | None |
| | than Resin | adsorbent | adsorbent | adsorbent | adsorbent | adsorbent | adsorbent | |
| | Thickness [μm] | 350 | 350 | 350 | 350 | 350 | 350 | 350 |

| | | | | | | | |
|---|---|---|---|---|---|---|---|
| Ratio of Thickness of First resin layer with | 71 | 71 | 71 | 71 | 71 | 71 | 71 |
| respect to total thickness of First resin | | | | | | | |
| layer and Second resin layer [%] | | | | | | | |
| Concentration of Sulfide-based phosphor | 5 | 5 | 5 | 5 | 5 | 5 | 5 |
| in Second resin layer [mass %] | | | | | | | |
| Amount of Sulfur-based phosphor used | 0.1 | 0.1 | 0.1 | 0.1 | 0.1 | 0.1 | 0.1 |
| [mg] | | | | | | | |
| Reflectance of Silver reflector (Initial) | 76.60% | 76.20% | 76.10% | 76.30% | 76.60% | 77.70% | 76.10% |
| Reflectance of Silver reflector (After 48 h) | 69.90% | 72.80% | 61.00% | 63.00% | 73.00% | 74.00% | 62.00% |

TABLE 2

| | | Comparative | Comparative | Comparative | Comparative | | | Comparative |
|---|---|---|---|---|---|---|---|---|
| | | Example 1 | Example 2 | Example 3 | Example 4 | Example 8 | Example 9 | Example 5 |
| Second resin layer | Ingredient other | (One layer only) | Sulfur-based | Sulfur-based | (One layer only) | Sulfur-based | Sulfur-based | Sulfur-based |
| | than Resin | Sulfur-based | phosphor | phosphor | Sulfur-based | phosphor | phosphor | phosphor |
| | | phosphor | (Coated) | (Coated) | phosphor | (Coated) | (Coated) | (Coated) |
| | | (Coated) | | Glass flakes | | | | |
| | Thickness [μm] | | 140 | 140 | | 210 | 245 | 280 |
| First resin layer | Ingredient other | | None | None | | Inorganic | Inorganic | Inorganic |
| | than Resin | | | | | adsorbent | adsorbent | adsorbent |
| | Thickness [μm] | | 350 | 350 | | 280 | 245 | 210 |

| | | | | | | | |
|---|---|---|---|---|---|---|---|
| Ratio of Thickness of First resin layer | N/A | 71 | 71 | N/A | 57 | 50 | 43 |
| with respect to total thickness of First | | | | | | | |
| resin layer and Second resin layer [%] | | | | | | | |
| Concentration of Sulfide-based | 2 | 5 | 5 | 2 | 5 | 5 | 5 |
| phosphor in Second resin layer | | | | | | | |
| [mass %] | | | | | | | |
| Amount of Sulfur-based phosphor | 0.14 | 0.1 | 0.1 | 0.14 | 0.1 | 0.1 | 0.1 |
| used [mg] | | | | | | | |
| Reflectance of Silver reflector | 76.30% | 76.30% | 77.80% | 76.00% | 76.60% | 76.20% | 77.00% |
| (Initial) | | | | | | | |
| Reflectance of Silver reflector | 24.80% | 31.20% | 35.00% | 15.00% | 65.00% | 60.20% | 52.00% |
| (After 48 h) | | | | | | | |

As can be seen from the results in Tables 1 and 2, the reflectance of the silver reflector of the light-emitting devices of Examples 1 to 9 was 60% or more even after 48 hours had passed since the devices were placed into the oven at 85° C., corrosion of the silver reflector as a silver-based member was sufficiently suppressed, and good performance such as good light-emission characteristics was maintained.

### INDUSTRIAL APPLICABILITY

The present disclosure provides a method of providing a light-emitting device excellent in light-emission characteristics, for which deterioration of performance such as deterioration of light-emission characteristics due to generation of sulfur-based gas is sufficiently suppressed, and a simple method of producing the light-emitting device.

### REFERENCE SIGNS LIST

1: Light-emitting device
2: Reflector
3: Light-emitting element
4: Resin layer
4a: First resin layer
4b: Second resin layer
5: Resin layer accommodation member
6: Lead frame
7: Substrate
8: Inorganic adsorbent
9: Sulfide-based phosphor
10: Coating film
10a: First silicon dioxide film
10b: Second silicon dioxide film
11: Metal oxide powder
15: Metal wire

1. A light-emitting device comprising:
a light-emitting element;
one or more silver-based members having silver on their surfaces; and
a resin layer including a first resin layer covering at least one of the silver-based members, and a second resin layer placed directly on the first resin layer,
wherein the light-emitting element is covered with the first resin layer or both the first resin layer and the second resin layer,
at least one of the first resin layer and the second resin layer contains an inorganic adsorbent which chemically adsorbs a sulfide,
the second resin layer contains a sulfide-based phosphor,
a ratio of a thickness of the first resin layer to be formed with respect to a total thickness of the first resin layer and the second resin layer to be formed is 50% or more, and
with respect to a silver corrosion test of the light-emitting device with a humidity of 100% RH and a temperature of 85° C., a difference between a reflectance for light of 560 nm of the silver-based members before the silver corrosion test and a reflectance for light of 560 nm of the silver-based members after the silver corrosion test for 48 hours is less than 25%.

2. The light-emitting device according to claim 1, wherein one of the first resin layer and the second resin layer which covers the light-emitting element contains the inorganic adsorbent.

3. The light-emitting device according to claim 1, wherein the thickness of the first resin layer is 240 μm or more.

4. The light-emitting device according to claim 1, wherein the inorganic adsorbent includes particles formed from a compound containing a metal element.

5. The light-emitting device according to claim 4, wherein the compound containing the metal element is selected from MgO, CaO, BaO, BaB₂O₄, SrO, La₂O₃, ZnO, Zn(OH)₂, ZnSO₄.nH₂O (0≤n≤7), ZnTi₂O₄, Zn₂Ti₃O₈, Zn₂TiO₄, ZnTiO₃, ZnBaO₂, ZnBa₂O₃, ZnGa₂O₄, Zn_{1.23}Ga_{0.28}O₂, Zn₃GaO₄, Zn₆Ga₂O₉, Zn_{0.125-0.95}Mg_{0.05-0.9}O, Zn_{0.1-0.75}Ca_{0.25-0.9}O, ZnSrO₂, Zn_{0.3}Al_{2.4}O₄, ZnAl₂O₄, Zn₃₋₇In₂O₆₋₁₀, ZnSnO₃, Zn₂SnO₄; and silicates containing a metal element selected from Cu, Zn, Mn, Co, Ni, Zr, Al, and lanthanide elements.

6. The light-emitting device according to claim 4, wherein the compound containing the metal element is ZnO.

7. The light-emitting device according to claim 1, wherein the first resin layer and the second resin layer contain one of a silicone resin and an epoxy resin.

8. The light-emitting device according to claim 1, wherein the resin layer contains glass flakes.

9. The light-emitting device according to claim 1, wherein one of the layers that compose the resin layer, which is farthest from the silver-based member covered with the first resin layer contains glass flakes.

10. The light-emitting device according to claim 1, wherein the sulfide-based phosphor includes a green phosphor represented by MGa₂S₄:Eu (M represents one or more elements including at least one of Sr, Ba, and Ca).

11. The light-emitting device according to claim 1, wherein the sulfide-based phosphor includes a green phosphor represented by SrGa₂S₄:Eu.

12. The light-emitting device according to claim 1, wherein the sulfide-based phosphor has, on its surface, a coating film including a first silicon dioxide film and a second silicon dioxide film on the first silicon dioxide, and at least one of the first silicon dioxide film and the second silicon dioxide film contains metal oxide powder.

13. The light-emitting device according to claim 12, wherein an outermost film of the silicon dioxide films that compose the coating film contains metal oxide powder.

14. The light-emitting device according to claim 12, wherein the metal oxide powder contains zinc oxide powder.

15. A method of producing the light-emitting device according to claim 1, comprising:
a step of preparing a reflector having silver on its surface, with a light-emitting element being provided on the reflector;
a step of forming a first resin layer by supplying a first resin composition so as to cover the reflector; and
a step of forming a second resin layer by supplying a second resin composition directly onto the first resin layer,
wherein at least one of the first resin composition and the second resin composition contains an inorganic adsorbent which chemically adsorbs a sulfide,
the second resin composition contains a sulfide-based phosphor, and
an amount of the first resin composition supplied and an amount of the second resin composition supplied are determined so that a ratio of a thickness of the first resin layer to be formed with respect to a total thickness of the first resin layer and the second resin layer to be formed will be 50% or more.

16. A light-emitting device comprising:
a light-emitting element;
one or more silver-based members having silver on their surfaces; and
a resin layer including a first resin layer covering at least one of the silver-based members, and a second resin layer placed directly on the first resin layer,
wherein the light-emitting element is covered with the first resin layer or both the first resin layer and the second resin layer,
at least one of the first resin layer and the second resin layer contains an inorganic adsorbent which chemically adsorbs a sulfide,
the second resin layer contains a sulfide-based phosphor,
a ratio of a thickness of the first resin layer to be formed with respect to a total thickness of the first resin layer and the second resin layer to be formed is 50% or more, and
a reflectance for light of 560 nm of the silver-based members after a silver corrosion test of the light-emitting device for 48 hours is 60% or more, wherein the silver corrosion test is with a humidity of 100% RH and a temperature of 85° C.
